(19) United States
(12) Patent Application Publication
(10) Pub. No.: US 2026/0305310 A1
(43) Pub. Date: Oct. 1, 2026

(54) SEMICONDUCTOR DEVICE

(71) Applicant: SAMSUNG ELECTRONICS CO., LTD., Suwon-si (KR)

(72) Inventors: Jisoo OH, Suwon-si (KR); Ki-Il KIM, Suwon-si (KR); Hyonwook RA, Suwon-si (KR); Changbea PARK, Suwon-si (KR); Sanghyun LEE, Suwon-si (KR); Kyungyub JEON, Suwon-si (KR)

(73) Assignee: SAMSUNG ELECTRONICS CO., LTD., Suwon-si (KR)

(21) Appl. No.: 19/350,736

(22) Filed: Oct. 6, 2025

(30) Foreign Application Priority Data
Mar. 28, 2025 (KR) 10-2025-0040639

(51) Int. Cl. H10W 20/41; H10W 20/43; H10D 30/00; H10D 30/01; H10D 62/13; H10D 64/23; H10D 84/01; H10D 84/83

(52) U.S. Cl. CPC H10W 20/435; H10W 20/43; H10D 30/019; H10D 30/503; H10D 62/151; H10D 64/256; H10D 84/0149; H10D 84/832

(57) ABSTRACT

A semiconductor device includes a first conductive structure, a liner in contact with a sidewall of the first conductive structure, a second conductive structure on the first conductive structure, and an etch stop layer in contact with a sidewall of the second conductive structure. A lower surface of the etch stop layer is in contact with an upper surface of the liner.

### CROSS-REFERENCE TO RELATED APPLICATIONS

This application claims priority under 35 U.S.C. § 119 to and the benefit of Korean Patent Application No. 10-2025-0040639, filed on Mar. 28, 2025, in the Korean Intellectual Property Office, the disclosure of which is incorporated herein by reference in its entirety.

### BACKGROUND

A semiconductor device includes an integrated circuit composed of MOS (Metal Oxide Semiconductor) field effect transistors (MOSFETs). As the size and design rule of the semiconductor device gradually shrink, a scale down of the MOS field effect transistors is also gradually accelerating. As the size of the MOS field effect transistors shrinks, operating characteristics of the semiconductor device may deteriorate. Accordingly, various methods have been studied to form the semiconductor device with improved performance while overcoming the limitations associated with high integration of the semiconductor device.

### SUMMARY

According to an aspect of the disclosure, a semiconductor device may include a first conductive structure; a liner in contact with a sidewall of the first conductive structure; a second conductive structure on the first conductive structure; and an etch stop layer in contact with a sidewall of the second conductive structure. A lower surface of the etch stop layer may be in contact with an upper surface of the liner.

According to an aspect of the disclosure, a semiconductor device may include a first conductive structure; a liner on the first conductive structure; an interlayer insulating layer on the liner; a second conductive structure on the first conductive structure; and an etch stop layer on the interlayer insulating layer. The interlayer insulating layer may be between the liner and the etch stop layer. A first opening and a second opening connected to the first opening may be in the interlayer insulating layer. A second portion of the first conductive structure may be in the first opening. A lower portion of the second conductive structure may be disposed in the second opening. A width of the second opening may be greater than a width of an upper surface of the first conductive structure.

According to an aspect of the disclosure, a semiconductor device may include a first conductive structure; a liner surrounding an upper portion of the first conductive structure; an interlayer insulating layer surrounding an upper portion of the liner; a second conductive structure on the first conductive structure; an etch stop layer on the interlayer insulating layer; and a cover insulating layer on the etch stop layer. The interlayer insulating layer may be between the liner and the etch stop layer. A sidewall of the upper portion of the liner may be in contact with the interlayer insulating layer. An upper surface of the upper portion of the liner may be in contact with the etch stop layer.

According to an aspect of the disclosure, a method of manufacturing a semiconductor device may include forming a preliminary conductive structure; forming a mask pattern on the preliminary conductive structure; etching the preliminary conductive structure using the mask pattern as an etching mask, the etched preliminary conductive structure may be referred to as a first conductive structure; forming a preliminary liner on the mask pattern and the first conductive structure; forming an interlayer insulating layer on the preliminary liner; removing the mask pattern; removing a portion of the preliminary liner to expose a sidewall of the interlayer insulating layer; and forming a second conductive structure on the first conductive structure.

According to an aspect of the disclosure, forming the second conductive structure may include: forming an etch stop layer covering the sidewall of the interlayer insulating layer; forming a cover insulating layer on the etch stop layer; patterning the etch stop layer using the cover insulating layer as an etch mask; and forming the second conductive structure in the cover insulating layer.

According to an aspect of the disclosure, forming the interlayer insulating layer may include: forming a preliminary insulating layer on the preliminary liner; and removing an upper portion of the preliminary liner and an upper portion of the preliminary insulating layer.

According to an aspect of the disclosure, removing the portion of the preliminary liner may include selectively removing the portion of the preliminary liner.

According to an aspect of the disclosure, a material included in the preliminary liner may have an etching selectivity with respect to a material included in the first conductive structure and the interlayer insulating layer.

According to an aspect of the disclosure, the mask pattern and the portion of the preliminary liner may be removed simultaneously.

### BRIEF DESCRIPTION OF DRAWINGS

FIG. 1A is a top view of a semiconductor device according to some embodiments.

FIG. 1B is a cross-sectional view taken along line A1-A1′ in FIG. 1A.

FIG. 1C is a cross-sectional view taken along line A2-A2′ in FIG. 1A.

FIG. 1D is an enlarged view of a region Q1 of FIG. 1B.

FIG. 1E is an enlarged view of a region Q2 of FIG. 1C.

FIGS. 2A, 2B, 3, 4, 5, 6, 7, 8, 9, 10A, 10B, 11A, and 11B, are cross-sectional views illustrating a method of manufacturing the semiconductor device according to some embodiments.

FIG. 12A is a top view of a semiconductor device according to some embodiments.

FIG. 12B is a cross-sectional view taken along line B1-B1′ in FIG. 12A.

FIG. 12C is a cross-sectional view taken along line B2-B2′ in FIG. 12A.

FIG. 12D is a cross-sectional view taken along line B3-B3′ in FIG. 12A.

FIG. 13 is an enlarged cross-sectional view of a semiconductor device according to some embodiments.

### DETAILED DESCRIPTION

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” As used herein, an expression “at least one of” preceding a list of elements modifies the entire list of the elements and does not modify the individual elements of the list. For example, an expression, “at least one of a, b, and c” and “at least one of a, b, or c” should be understood as including only a, only b, only c, both a and b, both a and c, both b and c, or all of a, b, and c.

In the specification, when an element is referred to as being “in contact” or “contacted” or the like to another element, the element may be in “electrical contact” or in “physical contact” with another element; or in “indirect contact” or in “direct contact” with another element.

Example embodiments of the disclosure will now be described more fully with reference to the accompanying drawings, in which example embodiments are shown.

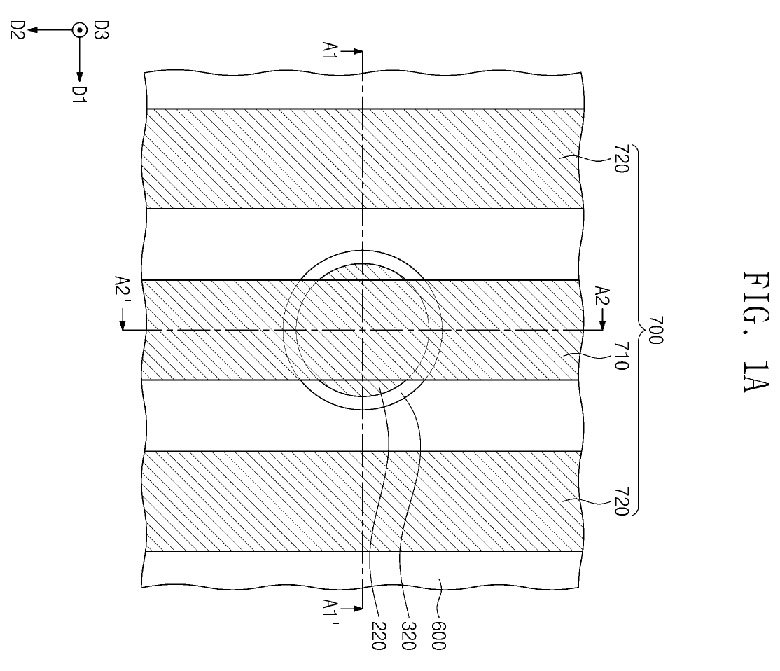

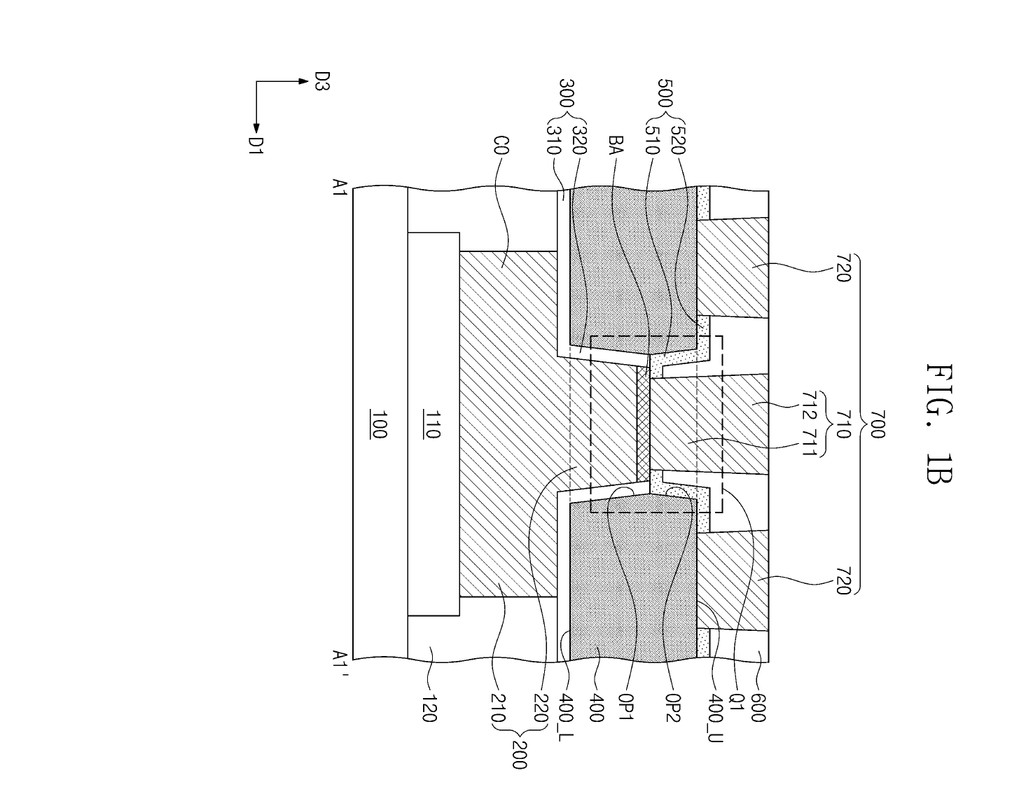

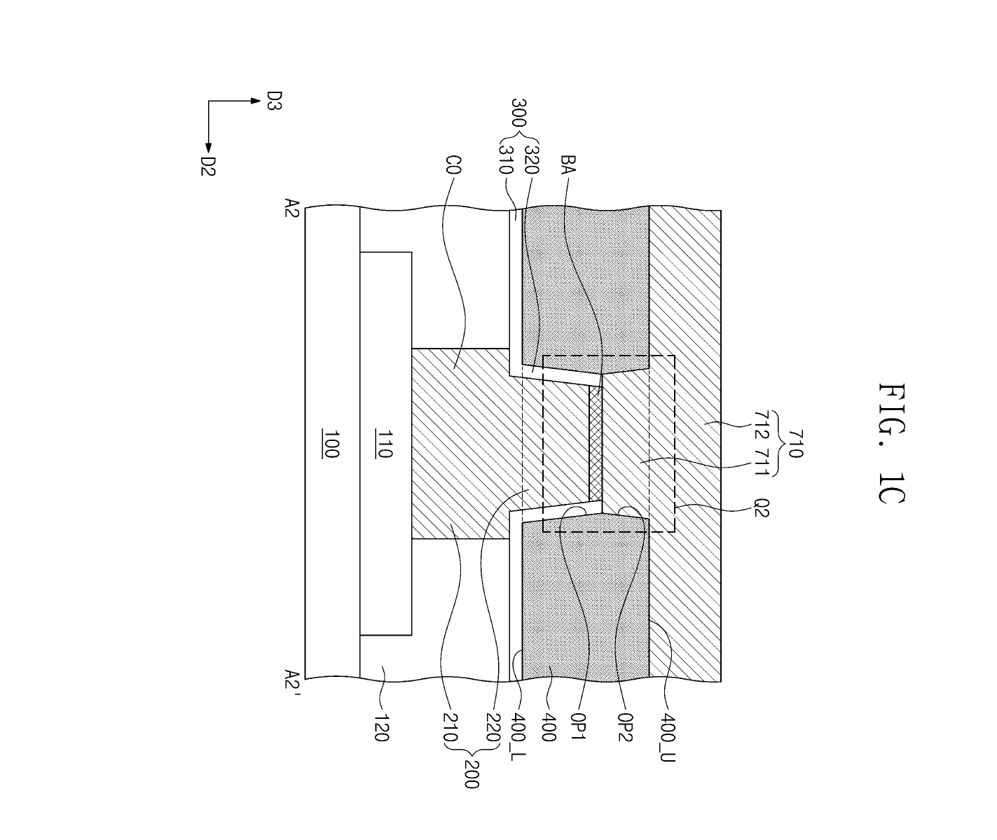

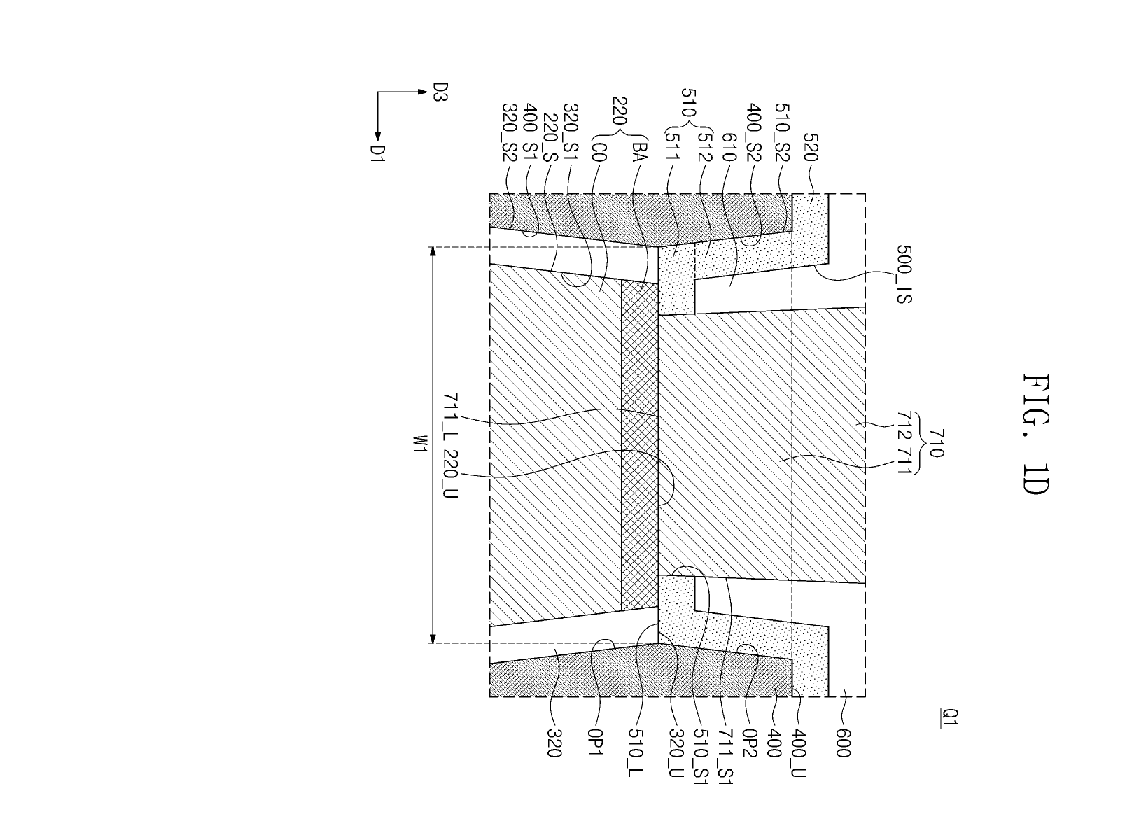

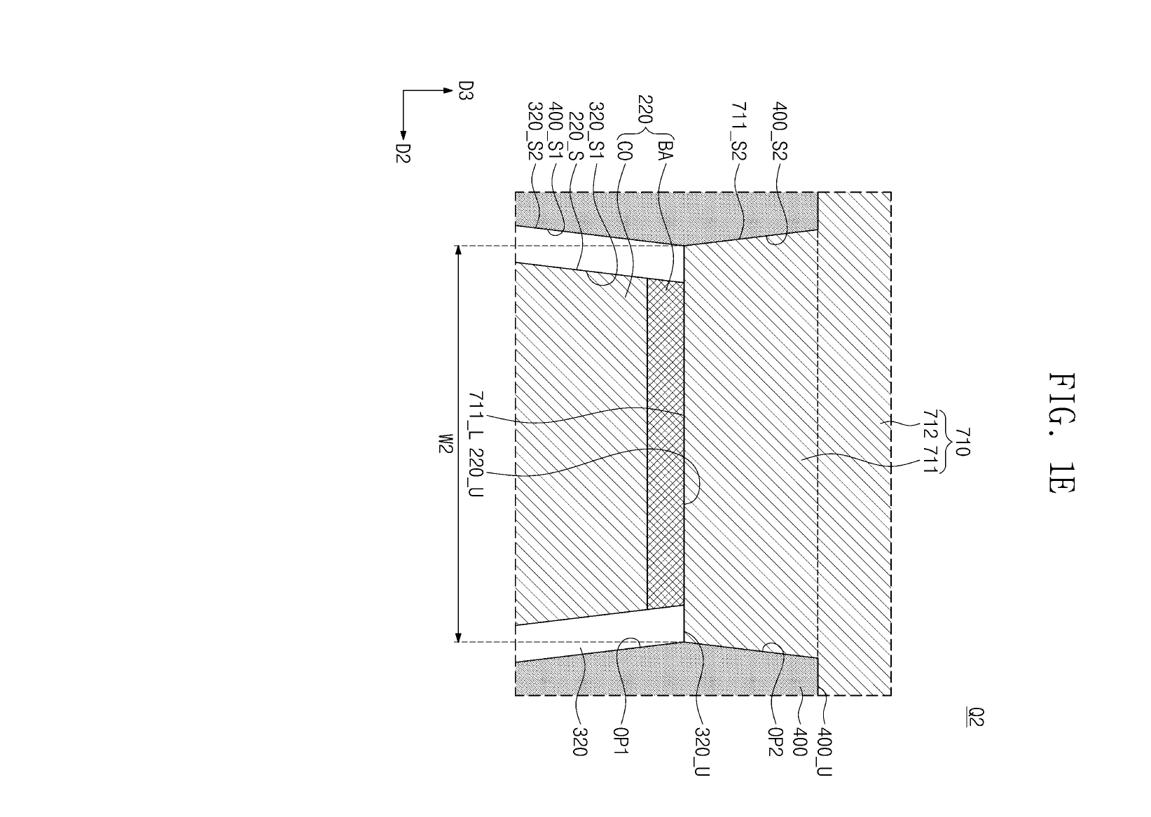

FIG. 1A is a top view of a semiconductor device according to some embodiments. FIG. 1B is a cross-sectional view taken along line A1-A1′ in FIG. 1A. FIG. 1C is a cross-sectional view taken along line A2-A2′ in FIG. 1A. FIG. 1D is an enlarged view of a region Q1 of FIG. 1B. FIG. 1E is an enlarged view of a region Q2 of FIG. 1C.

Referring to FIGS. 1A, 1B, and 1C, a semiconductor device may include a substrate 100.

The substrate 100 may have a shape of a plate extending along a plane defined by a first direction D1 and a second direction D2. The first direction D1 and the second direction D2 may intersect each other. For example, the first direction D1 and the second direction D2 may be horizontal directions orthogonal to each other. The first direction D1 and the second direction D2 may be parallel to an upper surface of the substrate 100.

The substrate 100 may be a semiconductor substrate, an insulator (insulating) substrate, or a semiconductor-on-insulator (SOI) substrate. The semiconductor substrate may include, for example, silicon, germanium, silicon-germanium, GaP, and/or GaAs.

An electronic device 110 may be disposed on the substrate 100. The electronic device 110 may include, for example, a transistor, a capacitor, a resistor, an inductor, a diode, an amplifier, and/or a power source. In another example, the electronic device 110 may include a memory device, a logic device, and/or an image sensor device.

A lower conductive structure 200 may be disposed on the electronic device 110. The lower conductive structure 200 may be electrically connected to the electronic device 110. The lower conductive structure 200 may include a conductive material.

The lower conductive structure 200 may include a conductive layer CO and a barrier layer BA. The conductive layer CO may be disposed on the electronic device 110. The barrier layer BA may be disposed on the conductive layer CO. The conductive layer CO and the barrier layer BA may include different conductive materials. For example, the conductive layer CO may include tungsten (W) or molybdenum (Mo), and the barrier layer BA may include titanium nitride (TiN), titanium (Ti), tantalum nitride (TaN), and/or tantalum (Ta).

The lower conductive structure 200 may include a lower portion 210 and an upper portion 220. The upper portion 220 of the lower conductive structure 200 may be a portion disposed in a first opening OP1 of an interlayer insulating layer 400 to be described later. The upper portion 220 of the lower conductive structure 200 may be a portion disposed at a higher level than a lower surface 400_Lof the interlayer insulating layer 400. The lower portion 210 of the lower conductive structure 200 may be a portion disposed at a lower level than the lower surface 400_Lof the interlayer insulating layer 400.

The lower portion 210 of the lower conductive structure 200 may include a lower portion of the conductive layer CO. The upper portion 220 of the lower conductive structure 200 may include an upper portion of the conductive layer CO and the barrier layer BA. A width of the lower portion 210 of the lower conductive structure 200 in the first direction D1 may be greater than a width of the upper portion 220 of the lower conductive structure 200 in the first direction D1. A width of the lower portion 210 of the lower conductive structure 200 in the second direction D2 may be greater than a width of the upper portion 220 of the lower conductive structure 200 in the second direction D2. The width of the upper portion 220 of the lower conductive structure 200 in the first direction D1 and the width of the upper portion 220 of the lower conductive structure 200 in the second direction D2 may decrease (or become smaller) as the level (or height) increases. In the disclosure, a level (or height) may be defined as a distance in a third direction D3 from an upper surface of the substrate 100. The third direction D3 may intersect the first direction D1 and the second direction D2. For example, the third direction D3 may be a vertical direction orthogonal to the first direction D1 and the second direction D2. The upper portion 220 of the lower conductive structure 200 may protrude from the lower portion 210 of the lower conductive structure 200 in the third direction D3. For example, the upper portion 220 of the lower conductive structure 200 may protrude upward from a central region of the lower portion 210 of the lower conductive structure 200 in the third direction D3.

In some embodiments, the upper portion 220 of the lower conductive structure 200 may have a shape of a line or bar extending in the second direction D2.

A lower insulating layer 120 may be disposed on the substrate 100 and the electronic device 110. The lower insulating layer 120 may surround the lower portion 210 of the lower conductive structure 200 and the electronic device 110. The lower insulating layer 120 may include an insulating material. In some embodiments, the lower insulating layer 120 may be a multilayer structure including a plurality of insulating layers.

A liner 300 may be disposed on the lower conductive structure 200 and the lower insulating layer 120. The liner 300 may surround the upper portion 220 of the lower conductive structure 200. The liner 300 may include an insulating material.

The liner 300 may include a lower portion 310 and an upper portion 320. The upper portion 320 of the liner 300 may be a portion disposed in the first opening OP1 of the interlayer insulating layer 400. The upper portion 320 of the liner 300 may be a portion disposed at a higher level than the lower surface 400_L of the interlayer insulating layer 400. The lower portion 310 of the liner 300 may be a portion disposed at a lower level than the lower surface 400_Lof the interlayer insulating layer 400.

An interlayer insulating layer 400 may be disposed on the liner 300. The interlayer insulating layer 400 may surround the upper portion 320 of the liner 300 and the upper portion 220 of the lower conductive structure 200.

The first opening OP1 and a second opening OP2 may be defined by (or formed in) the interlayer insulating layer 400. The first opening OP1 and the second opening OP2 may be connected to each other. As the level (or height) of the first opening OP1 increases, a width of the first opening OP1 in the first direction D1 and a width of the first opening OP1 in the second direction D2 may decrease. As the level (or height) of the second opening OP2 increases, a width of the second opening OP2 in the first direction D1 and a width of the second opening OP2 in the second direction D2 may increase. As the first opening OP1 approaches (or is closer to) the second opening OP2, the width of the first opening OP1 in the first direction D1 and the width of the first opening OP1 in the second direction D2 may decrease (or become smaller). As the second opening OP2 approaches (or is closer to) the first opening OP1, the width of the second opening OP2 in the first direction D1 and the width of the second opening OP2 in the second direction D2 may decrease (or become smaller).

The interlayer insulating layer 400 may include an insulating material. A material included in the interlayer insulating layer 400 and a material included in the liner 300 may have an etching selectivity with respect to each other. For example, the interlayer insulating layer 400 may include silicon nitride, and the liner 300 may include silicon oxide, aluminum oxide, and/or aluminum nitride.

In some embodiments, the liner 300 may include a low dielectric constant material. In an example, the liner 300 may include silicon oxide.

An etch stop layer 500 may be disposed on the interlayer insulating layer 400. The interlayer insulating layer 400 may be disposed between the etch stop layer 500 and the liner 300. The etch stop layer 500 may include an insulating material.

The etch stop layer 500 may include a lower portion 510 and an upper portion 520. The lower portion 510 of the etch stop layer 500 may be a portion disposed in the second opening OP2 of the interlayer insulating layer 400. The lower portion 510 of the etch stop layer 500 may be a portion disposed at a lower level than an upper surface 400_U of the interlayer insulating layer 400. The upper portion 520 of the etch stop layer 500 may be a portion disposed at a higher level than the upper surface 400_U of the interlayer insulating layer 400.

The material included in the interlayer insulating layer 400 and a material included in the etch stop layer 500 may have an etching selectivity with respect to each other. For example, the interlayer insulating layer 400 may include silicon nitride, and the etch stop layer 500 may include aluminum oxide.

A cover insulating layer 600 may be disposed on the etch stop layer 500. The cover insulating layer 600 may include an insulating material.

An upper conductive structure 700 may be provided or formed. The upper conductive structure 700 may penetrate the cover insulating layer 600 and the etch stop layer 500 in the third direction D3. The upper conductive structure 700 may include a first upper conductive structure 710 on the lower conductive structure 200 and the interlayer insulating layer 400, and a second upper conductive structure 720 on the interlayer insulating layer 400. The first upper conductive structure 710 may be in contact with the lower conductive structure 200. The second upper conductive structure 720 may be spaced apart from the lower conductive structure 200. The upper conductive structure 700 may include an insulating material.

The first upper conductive structure 710 may include a lower portion 711 and an upper portion 712. The lower portion 711 of the first upper conductive structure 710 may be a portion disposed in the second opening OP2 of the interlayer insulating layer 400. The lower portion 711 of the first upper conductive structure 710 may be a portion disposed at a lower level than the upper surface 400_U of the interlayer insulating layer 400. The upper portion 712 of the first upper conductive structure 710 may be a portion disposed at a higher level than the upper surface 400_U of the interlayer insulating layer 400.

The upper conductive structure 700 may have a shape of a line or a bar extending in the second direction D2. For example, a plurality of upper conductive structures 700 may be arranged to be spaced apart from each other in the first direction D1.

In some embodiments, the upper conductive structure 700 may have a shape of a via.

Referring to FIGS. 1D and 1E, the upper portion 320 of the liner 300 may be in contact with a sidewall 220_S of the upper portion 220 of the lower conductive structure 200. The sidewall 220_S of the upper portion 220 of the lower conductive structure 200 may include a sidewall of the barrier layer BA and a sidewall of the upper portion of the conductive layer CO.

The upper portion 320 of the liner 300 may include a first sidewall 320_S1 in contact with the sidewall 220_S of the upper portion 220 of the lower conductive structure 200 and a second sidewall 320_S2 in contact with the interlayer insulating layer 400. The interlayer insulating layer 400 may include a first sidewall 400_S1 that is in contact with the second sidewall 320_S2 of the upper portion 320 of the liner 300. The first opening OP1 may be defined by (or formed in) the first sidewall 400_S1 of the interlayer insulating layer 400.

The lower portion 510 of the etch stop layer 500 may be in contact with a first sidewall 711_S1 of the lower portion 711 of the first upper conductive structure 710. The lower portion 510 of the etch stop layer 500 may include a first sidewall 510_S1 in contact with the first sidewall 711_S1 of the lower portion 711 of the first upper conductive structure 710 and a second sidewall 510_S2 in contact with the interlayer insulating layer 400. The interlayer insulating layer 400 may include a second sidewall 400_S2 that is in contact with the second sidewall 510_S2 of the lower portion 510 of the etch stop layer 500. The second opening OP2 may be defined by (or formed in) the second sidewall 400_S2 of the interlayer insulating layer 400.

The second sidewall 510_S2 of the lower portion 510 of the etch stop layer 500 may be connected to the second sidewall 320_S2 of an upper portion 320 of the liner 300. In the cross-sectional view of FIG. 1D, the second sidewall 510_S2 of the lower portion 510 of the etch stop layer 500 may be in contact with the second sidewall 320_S2 of the upper portion 320 of the liner 300.

The etch stop layer 500 may include an inclined surface 500_IS opposite to the second sidewall 510_S2 of the lower portion 510 of the etch stop layer 500. The inclined surface 500_IS may be inclined with respect to the first direction D1 and the second direction D2.

A second sidewall 711_S2 of the lower portion 711 of the first upper conductive structure 710 may be in contact with the second sidewall 400_S2 of the interlayer insulating layer 400.

A lower surface 510_L of the lower portion 510 of the etch stop layer 500 may be in contact with an upper surface 320_U of the upper portion 320 of the liner 300. The lower surface 510_L of the lower portion 510 of the etch stop layer 500 may be in contact with an upper surface 220_U of the upper portion 220 of the lower conductive structure 200. The upper surface 220_U of the upper portion 220 of the lower conductive structure 200 may be an upper surface of the barrier layer BA.

A lower surface 711_L of the lower portion 711 of the first upper conductive structure 710 may be in contact with the upper surface 220_U of the upper portion 220 of the lower conductive structure 200 and the upper surface 320_U of the upper portion 320 of the liner 300.

The upper surface 220_U of the upper portion 220 of the lower conductive structure 200 and the upper surface 320_U of the upper portion 320 of the liner 300 may be coplanar. The upper surface 220_U of the upper portion 220 of the lower conductive structure 200 and the upper surface 320_U of the upper portion 320 of the liner 300 may be disposed at the same level (or same height).

The lower surface 510_L of the lower portion 510 of the etch stop layer 500 and the lower surface 711_L of the lower portion 711 of the first upper conductive structure 710 may be coplanar. The lower surface 510_L of the lower portion 510 of the etch stop layer 500 and the lower surface 711_L of the lower portion 711 of the first upper conductive structure 710 may be disposed at the same level (or same height).

The width of the second opening OP2 in the first direction D1 may be greater than the width of the upper surface 220_U of the upper portion 220 of the lower conductive structure 200 in the first direction D1. A minimum width W1 of the second opening OP2 in the first direction D1 may be greater than the width of the upper surface 220_U of the upper portion 220 of the lower conductive structure 200 in the first direction D1. The minimum width W1 of the second opening OP2 in the first direction D1 may be a width W1 of a lowermost portion of the second opening OP2 in the first direction D1. The width W1 of the lowermost portion of the second opening OP2 in the first direction D1 may be the same as a width of an uppermost portion of the first opening OP1 in the first direction D1.

The width of the second opening OP2 in the second direction D2 may be greater than the width of the upper surface 220_U of the upper portion 220 of the lower conductive structure 200 in the second direction D2. A minimum width W2 of the second opening OP2 in the second direction D2 may be greater than the width of the upper surface 220_U of the upper portion 220 of the lower conductive structure 200 in the second direction D2. The minimum width W2 of the second opening OP2 in the second direction D2 may be a width W2 of a lowermost portion of the second opening OP2 in the second direction D2. The width W2 of the lowermost portion of the second opening OP2 in the second direction D2 may be the same as a width of the uppermost portion of the first opening OP1 in the second direction D2.

The lower portion 510 of the etch stop layer 500 may include a first portion 511 that is in contact with the first upper conductive structure 710 and a second portion 512 that is spaced apart from the first upper conductive structure 710. The first portion 511 of the lower portion 510 of the etch stop layer 500 may be in contact with the first sidewall 711_S1 of the lower portion 711 of the first upper conductive structure 710. The first sidewall 510_S1 of the lower portion 510 of the etch stop layer 500 may be a sidewall of the first portion 511 of the lower portion 510 of the etch stop layer 500. The second portion 512 of the lower portion 510 of the etch stop layer 500 may be disposed at a higher level than the first portion 511 of the lower portion 510 of the etch stop layer 500. The second portion 512 of the lower portion 510 of the etch stop layer 500 may be spaced apart from the first sidewall 711_S1 of the lower portion 711 of the first upper conductive structure 710.

The cover insulating layer 600 may include a portion 610 interposed between the second portion 512 of the lower portion 510 of the etch stop layer 500 and the lower portion 711 of the first upper conductive structure 710.

A width of the lower surface 711_L of the lower portion 711 of the first upper conductive structure 710 in the first direction D1 may be smaller than a width of the upper surface 220_U of the upper portion 220 of the lower conductive structure 200 in the first direction D1. A width of the lower surface 711_L of the lower portion 711 of the first upper conductive structure 710 in the second direction D2 may be greater than a width of the upper surface 220_U of the upper portion 220 of the lower conductive structure 200 in the second direction D2.

In the semiconductor device according to some embodiments, as the liner 300 surrounds the upper portion 220 of the lower conductive structure 200 and includes a low dielectric constant material, electrical characteristic of the lower conductive structure 200 may be improved.

In the semiconductor device according to some embodiments, as the width of the second opening OP2 is greater than the width of the upper surface 220_U of the lower conductive structure 200, a space in which the first upper conductive structure 710 is formed may be sufficiently large. Accordingly, in a process of forming the first upper conductive structure 710, an occurrence of undercut of the etch stop layer 500 may be prevented, and a formation of voids may be prevented from being formed.

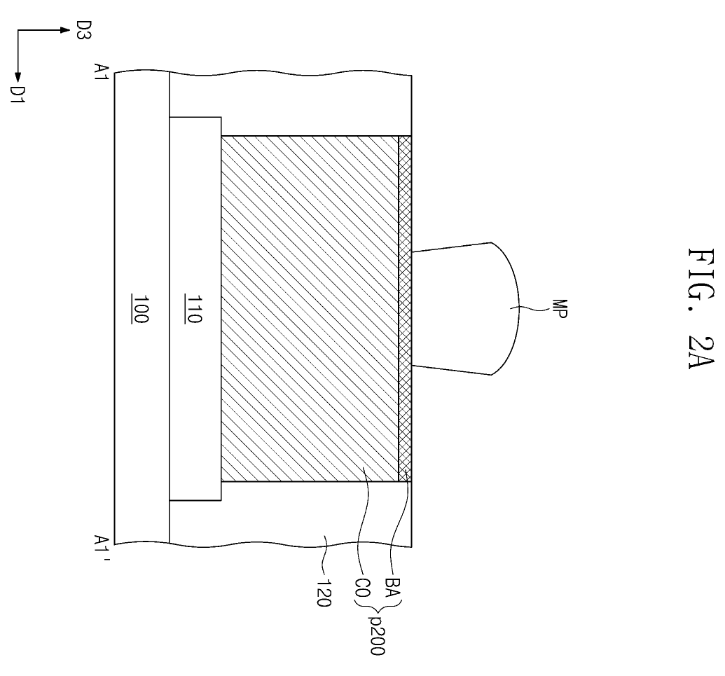

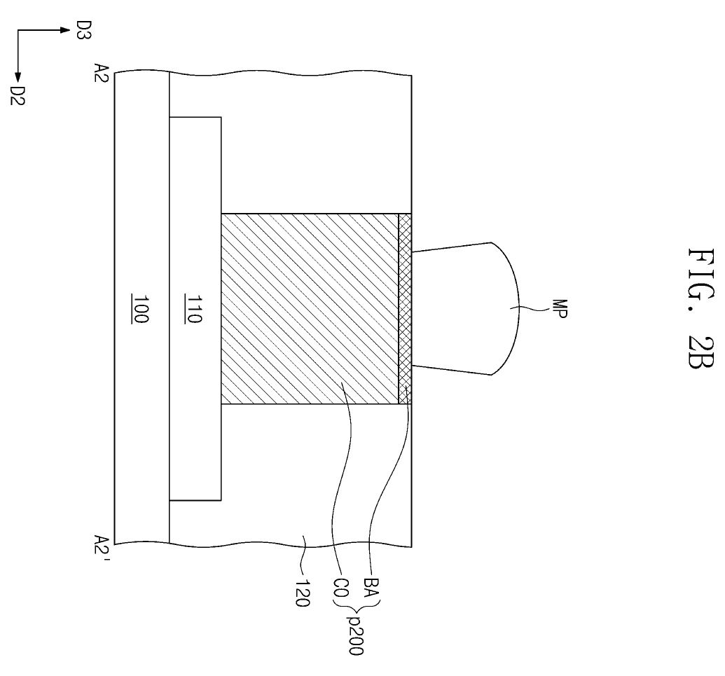

FIGS. 2A, 2B, 3, 4, 5, 6, 7, 8, 9, 10A, 10B, 11A, and 11B, are cross-sectional views illustrating a method of manufacturing the semiconductor device according to some embodiments.

Referring to FIGS. 2A and 2B, the electronic device 110 may be formed on the substrate 100. A preliminary conductive structure p200 and the lower insulating layer 120 may be formed on the electronic device 110. The lower insulating layer 120 may surround the preliminary conductive structure p200.

The preliminary conductive structure p200 may include the conductive layer CO and the barrier layer BA.

A first mask pattern MP may be formed on the preliminary conductive structure p200. Forming the first mask pattern MP may include forming a first mask layer on the preliminary conductive structure p200 and the lower insulating layer 120, and patterning the first mask layer.

The first mask pattern MP may include an insulating material. For example, the first mask pattern MP may include silicon oxide. A material included in the first mask pattern MP may have an etching selectivity with respect to a material included in the lower insulating layer 120.

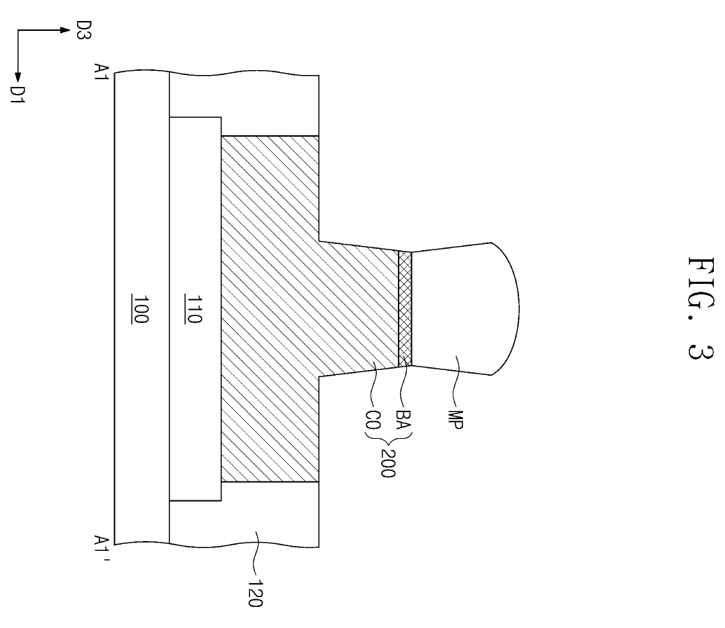

Referring to FIG. 3, the preliminary conductive structure p200 and the lower insulating layer 120 may be etched using the first mask pattern MP as an etching mask. The preliminary conductive structure p200 may be etched to form the lower conductive structure 200.

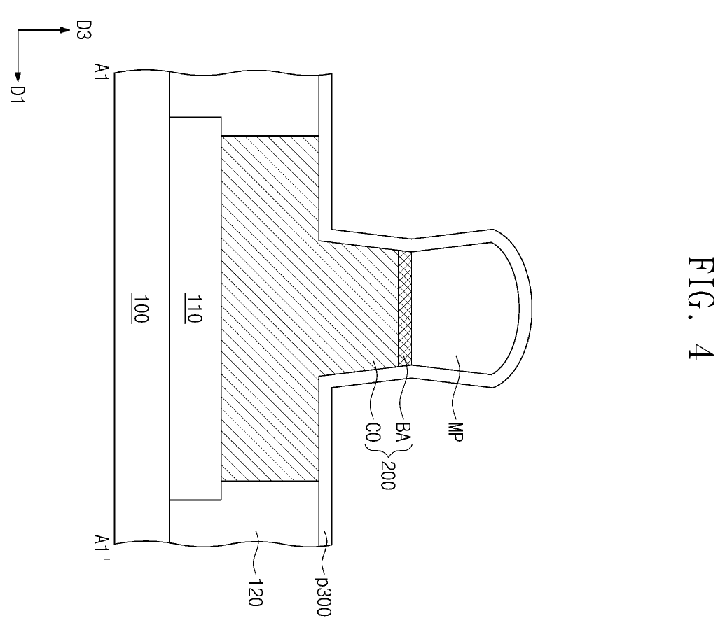

Referring to FIG. 4, a preliminary liner p300 may be formed on the lower conductive structure 200, the lower insulating layer 120, and the first mask pattern MP. The preliminary liner p300 may be formed to have a conformal thickness. The preliminary liner p300 may include an insulating material.

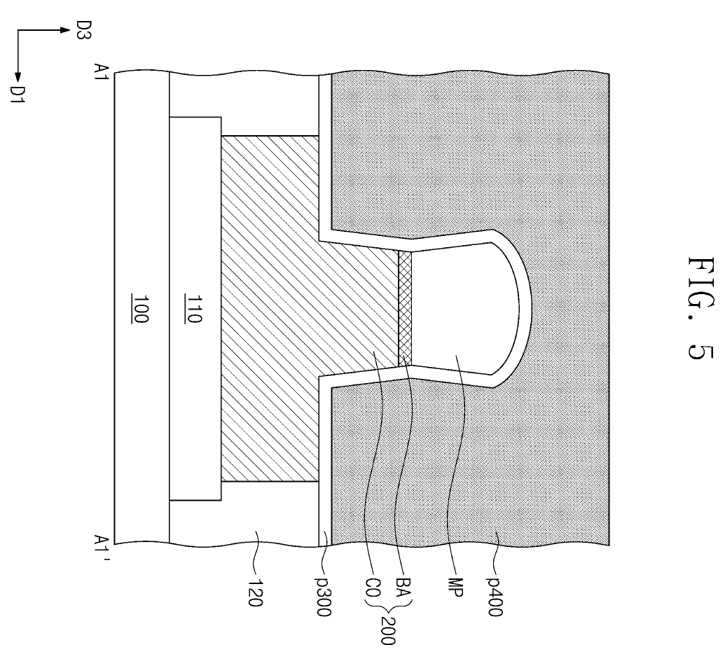

Referring to FIG. 5, a preliminary insulating layer p400 may be formed on the preliminary liner p300. The preliminary insulating layer p400 may include an insulating material. For example, the preliminary insulating layer p400 may include silicon nitride.

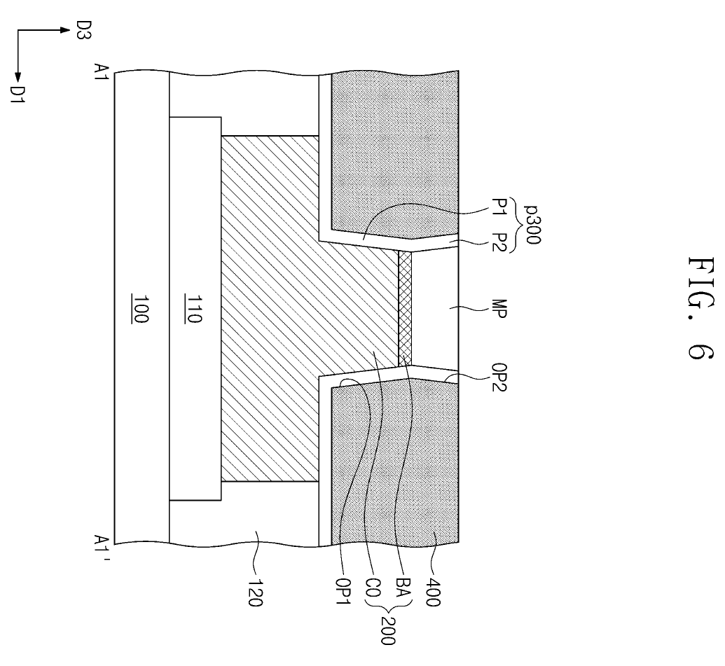

Referring to FIG. 6, an upper portion of the preliminary liner p300, an upper portion the first mask pattern MP, and an upper portion the preliminary insulating layer p400 may be removed. For example, the upper portion of the preliminary liner p300, the upper portion of the first mask pattern MP, and the upper portion of the preliminary insulating layer p400 may be simultaneously removed by a chemical mechanical polishing (CMP) process.

The preliminary insulating layer p400, from which the upper portion is removed, may be defined as (or referred to as) the interlayer insulating layer 400. The first opening OP1 and the second opening OP2 of the interlayer insulating layer 400 may be formed by removing the upper portion of the preliminary insulating layer p400. The first mask pattern MP may be disposed in the second opening OP2. The preliminary liner p300 may include a first portion P1 disposed in the first opening OP1 and a second portion P2 disposed in the second opening OP2. The upper portion of the preliminary liner p300 and the upper portion of the preliminary insulating layer p400 may be removed to expose an upper surface of the second portion P2 of the preliminary liner p300.

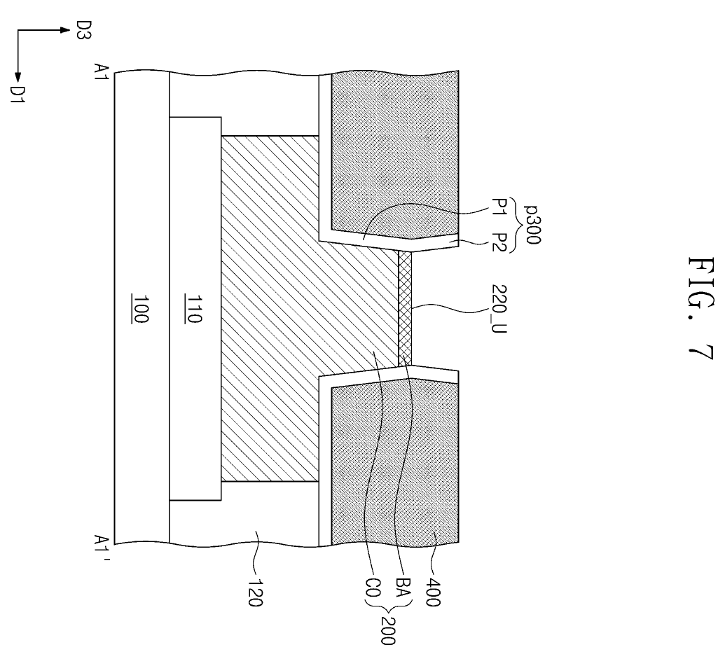

Referring to FIG. 7, the first mask pattern MP may be selectively removed. In some embodiments, a material included in the first mask pattern MP may have an etch selectivity with respect to a material included in the barrier layer BA of the lower conductive structure 200, the interlayer insulating layer 400 and a preliminary liner p300, and the first mask pattern MP may be selectively removed using an etchant capable of selectively etching or removing the first mask pattern MP. For example, the first mask pattern MP may include silicon oxide, the barrier layer BA of the lower conductive structure 200 may include TiN, Ti, TaN, and/or Ta, the interlayer insulating layer 400 may include silicon nitride, the preliminary liner p300 may include aluminum nitride or aluminum oxide, and hydrofluoric acid (HF) may be used as an etchant to selectively etch or remove the first mask pattern MP.

The first mask pattern MP may be removed to expose the upper surface 220_U of the lower conductive structure 200. The first mask pattern MP may be removed to expose the barrier layer BA. The first mask pattern MP may be removed to expose a sidewall of the second portion P2 of the preliminary liner p300. The second portion P2 of the preliminary liner p300 may be exposed, and the first portion P1 of the preliminary liner p300 may not be exposed. The first portion P1 of the preliminary liner p300 may be covered by the interlayer insulating layer 400 and the lower conductive structure 200, thereby not being exposed.

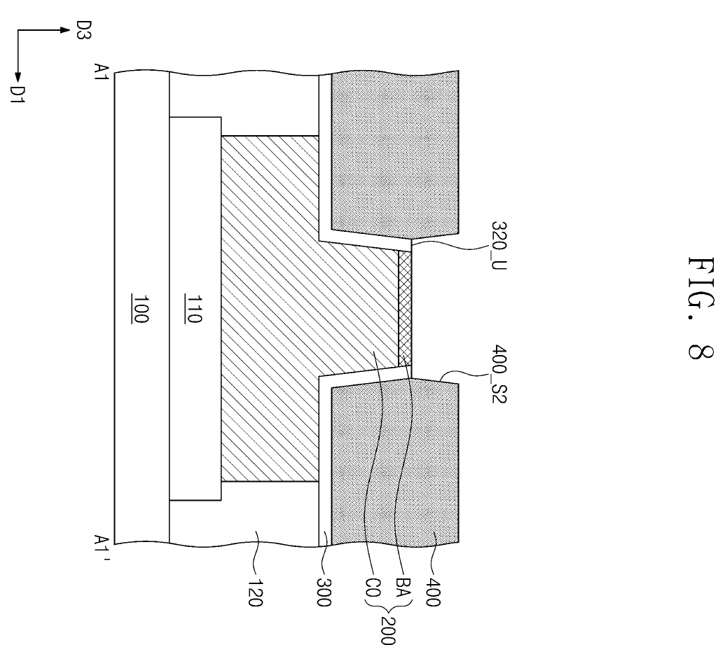

Referring to FIG. 8, the second portion P2 of the preliminary liner p300 may be selectively removed. In some embodiments, a material included in the preliminary liner p300 may have an etch selectivity with respect to a material included in the barrier layer BA of the lower conductive structure 200 and the interlayer insulating layer 400, and the second portion P2 of the preliminary liner p300 may be selectively removed using an etchant capable of selectively etching or removing the preliminary liner p300. For example, the preliminary liner p300 may include aluminum nitride or aluminum oxide, the barrier layer BA of the lower conductive structure 200 may include TiN, Ti, TaN, and/or Ta, and the interlayer insulating layer 400 may include silicon nitride. For example, the second portion P2 of the preliminary liner p300 may be selectively removed using hydrogen peroxide water as an etchant.

The preliminary liner p300 from which the second portion P2 has been removed may be defined as the liner 300. The second portion P2 may be removed to expose the upper surface 320_U of the liner 300. The second portion P2 may be removed to expose the second sidewall 400_S2 of the interlayer insulating layer 400.

In some embodiments, unlike those shown in FIGS. 7 and 8, the first mask pattern MP and the second portion P2 of the preliminary liner p300 may be removed simultaneously in a single process. For example, the first mask pattern MP and the preliminary liner p300 may include the same material. For example, the first mask pattern MP and the preliminary liner p300 may include silicon oxide, the barrier layer BA of the lower conductive structure 200 may include TiN, Ti, TaN, and/or Ta, and the interlayer insulating layer 400 may include silicon nitride. For example, hydrofluoric acid (HF) may be used as an etchant to selectively remove the first mask pattern MP and the second portion P2 of the preliminary liner p300.

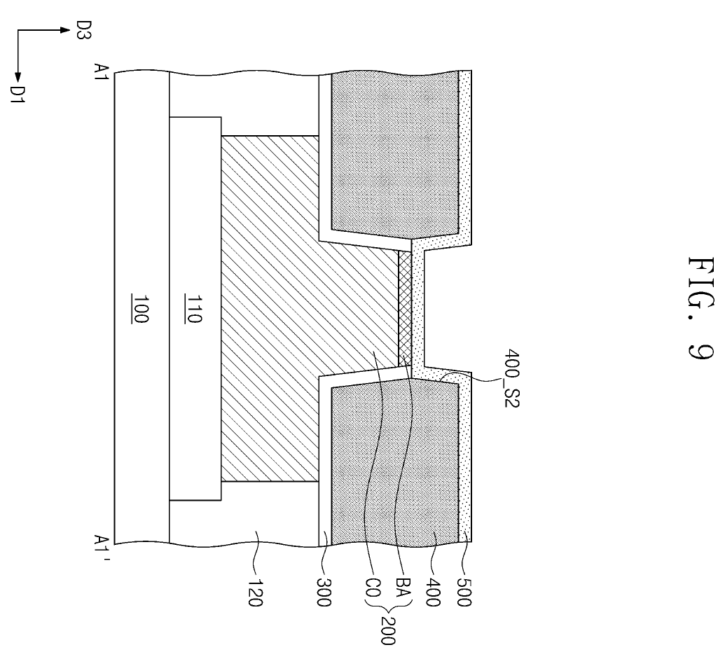

Referring to FIG. 9, the etch stop layer 500 may be formed on the liner 300, the lower conductive structure 200, and the interlayer insulating layer 400. The etch stop layer 500 may include an insulating material. The etch stop layer 500 may be formed to have a conformal thickness. The etch stop layer 500 may cover the second sidewall 400_S2 of the interlayer insulating layer 400.

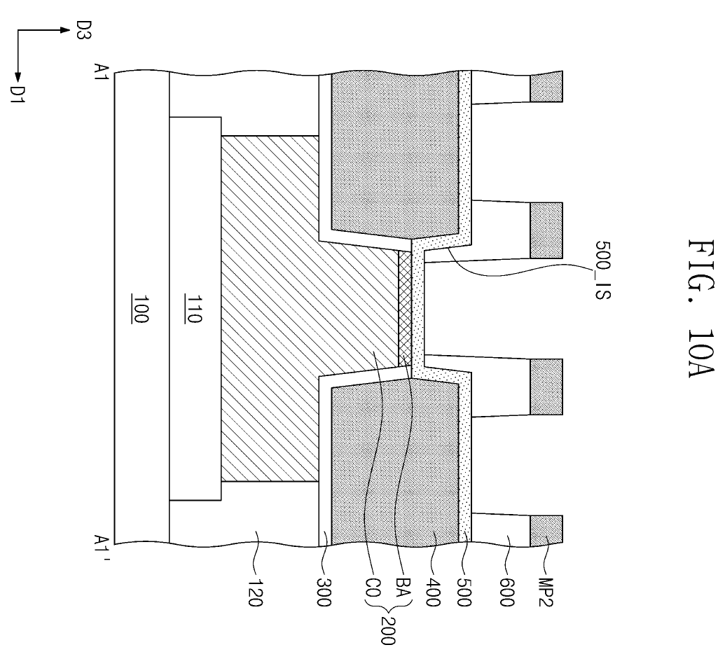

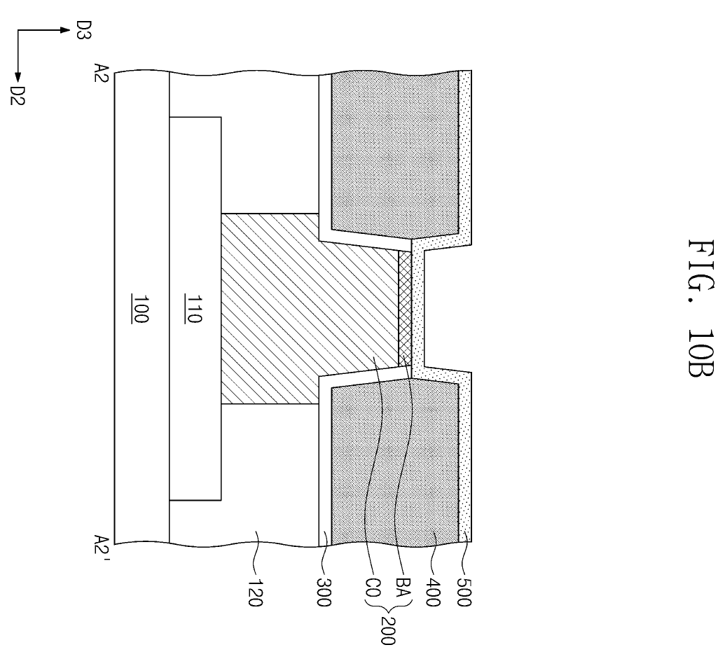

Referring to FIGS. 10A and 10B, the cover insulating layer 600 and a second mask pattern MP2 may be formed on the etch stop layer 500. The second mask pattern MP2 may have the shape of a line or bar extending in the second direction D2. The second mask patterns MP2 may be arranged in the first direction D1. The second mask pattern MP2 may be disposed on the cover insulating layer 600. The cover insulating layer 600 and the second mask pattern MP2 may include different insulating materials. For example, the cover insulating layer 600 may include a low dielectric constant material, and the second mask pattern MP2 may include TiN or tungsten carbide (WC).

The cover insulating layer 600 may cover the inclined surface 500_IS of the etch stop layer 500. The inclined surface 500_IS of the etch stop layer 500 may not be exposed by the cover insulating layer 600.

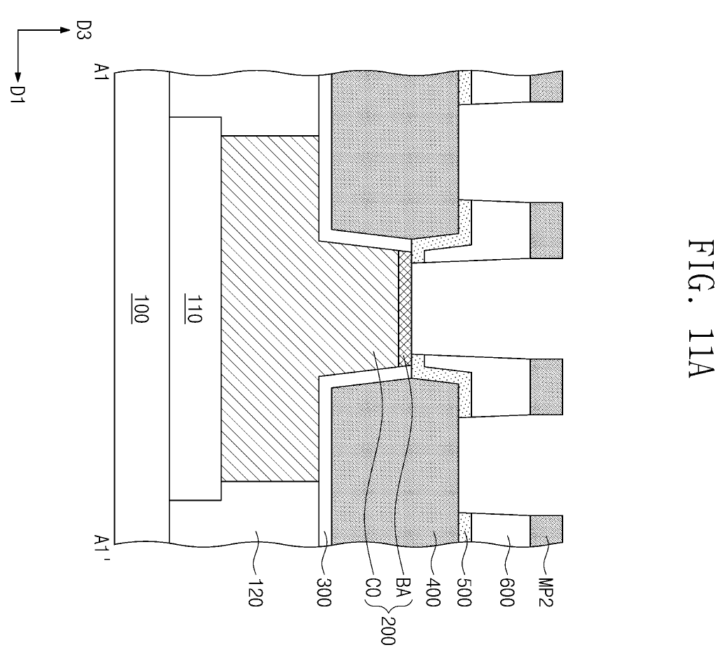

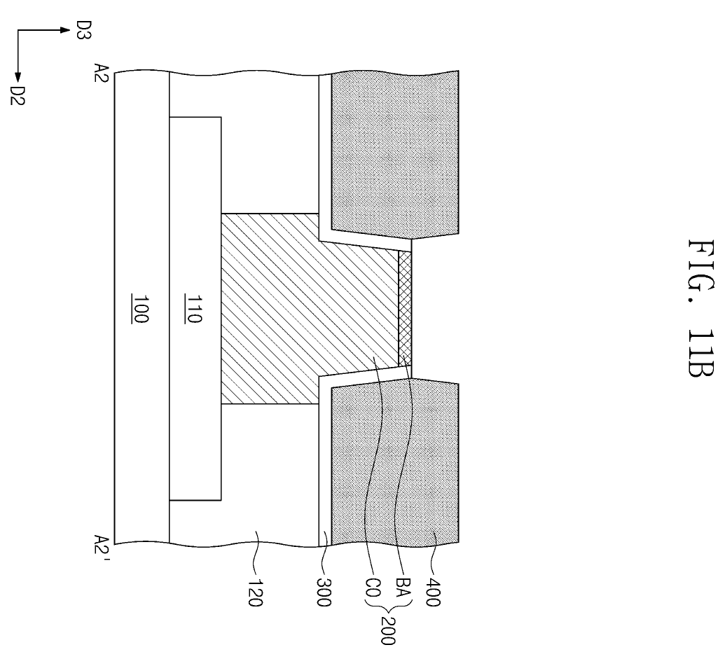

Referring to FIGS. 11A and 11B, the cover insulating layer 600 and the second mask pattern MP2 may be used as an etching mask to pattern the etch stop layer 500. The etch stop layer 500 may be patterned to expose the lower conductive structure 200.

Referring to FIGS. 1A to 1C, the upper conductive structure 700 may be formed. The upper conductive structure 700 may be formed in the cover insulating layer 600.

The method of manufacturing the semiconductor device according to some embodiments may include a process of forming the preliminary liner p300 and a process of removing the second portion P2 of the preliminary liner p300, so that the second opening OP2 of the interlayer insulating layer 400 may be relatively large. Accordingly, the inclined surface 500_IS of the etch stop layer 500 may be covered (e.g., completely covered) by the cover insulating layer 600, and undercutting of the etch stop layer 500 in a process of etching the cover insulating layer 600 may be prevented.

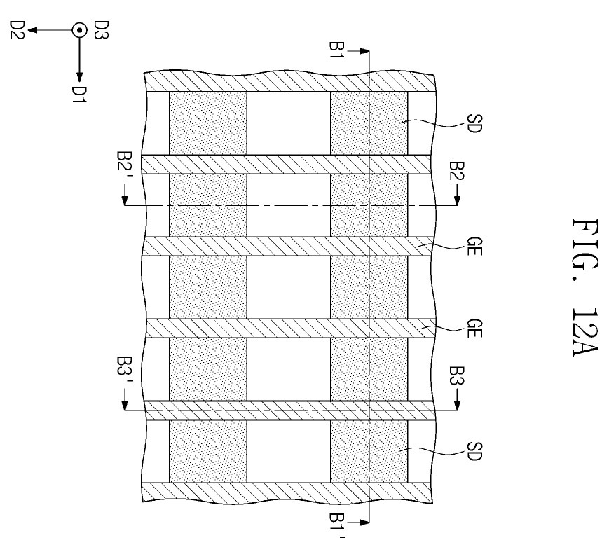

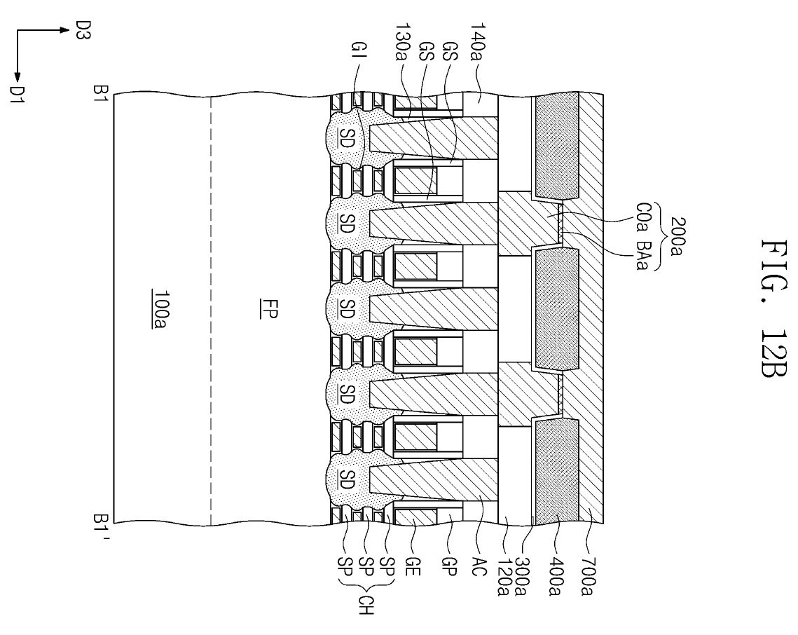

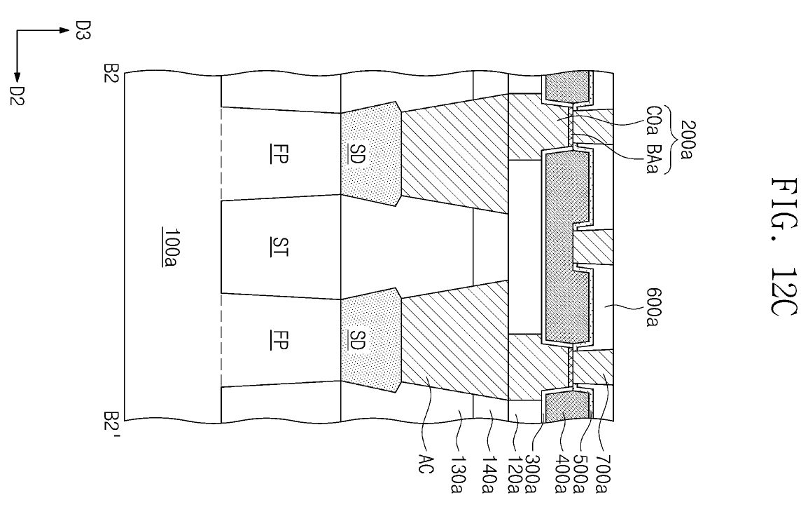

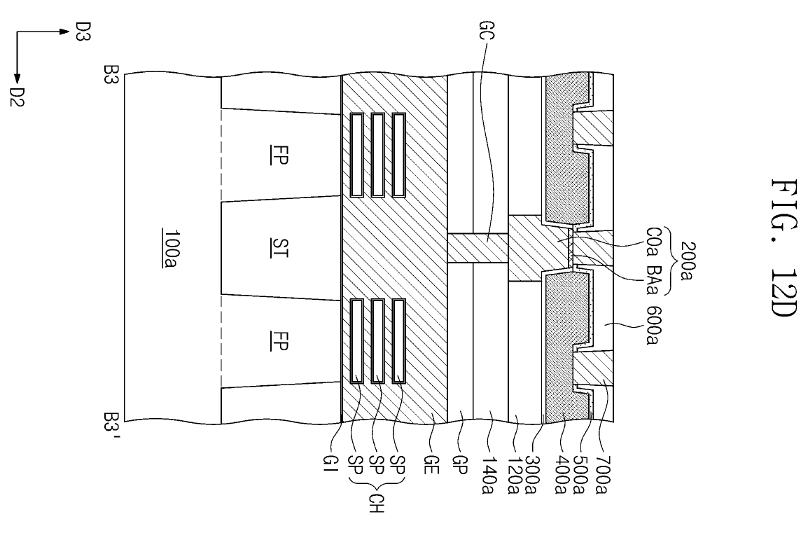

FIG. 12A is a top view of a semiconductor device according to some embodiments. FIG. 12B is a cross-sectional view taken along line B1-B1′ in FIG. 12A. FIG. 12C is a cross-sectional view taken along line B2-B2′ in FIG. 12A. FIG. 12D is a cross-sectional view taken along line B3-B3′ in FIG. 12A. The semiconductor device according to FIGS. 12A to 12D may be similar to the semiconductor device according to FIG. 1A to 1E, except as described below.

Referring to FIGS. 12A, 12B, 12C, and 12D, the semiconductor device may include a substrate 100a.

The substrate 100a may include a fin pattern FP. The fin pattern FP may be portion protruding from the substrate 100a in the third direction D3.

A device isolation layer ST may be disposed on the substrate 100a. The device isolation layer ST may surround the fin pattern FP. The device isolation layer ST may include an insulating material. For example, the device isolation layer ST may include an oxide.

A source/drain pattern SD may be disposed on the fin pattern FP. The source/drain pattern SD may be an epitaxial pattern formed by a selective epitaxial growth (SEG) process. The source/drain pattern SD may include a semiconductor material. For example, the source/drain pattern SD may include at least one of silicon (Si), silicon-germanium (SiGe), and germanium (Ge). The source/drain pattern SD may be doped with dopants.

A channel structure CH overlapping the fin pattern FP in the third direction D3 may be provided or formed. The channel structure CH may include semiconductor patterns SP overlapping in the third direction D3. In some embodiments, the semiconductor patterns SP may include silicon (Si). For example, the semiconductor patterns SP may include crystalline silicon. In some embodiments, the semiconductor patterns SP may include silicon-germanium (SiGe).

A gate electrode GE overlapping the channel structure CH in the third direction D3 may be provided or formed. The gate electrode GE may include a portion interposed between the semiconductor patterns SP. The gate electrode GE may include a conductive material. The semiconductor patterns SP, the channel structure CH and the gate electrode GE may constitute a three-dimensional field effect transistor (e.g., a multi‑bridge channel field effect transistor (MBCFET) or a gate‑all‑around field effect transistor (GAAFET)).

A gate insulating layer GI may be provided or formed. The gate insulating layer GI may be in contact with the gate electrode GE. The gate insulating layer GI may separate the gate electrode GE from the source/drain pattern SD and the semiconductor patterns SP. The gate insulating layer GI may include an insulating material. For example, the gate insulating layer GI may include an oxide.

A gate spacer GS may be provided or formed. A pair of gate spacers GS may be disposed on sides (e.g., opposite sides) of the gate electrode GE. The gate spacer GS may include an insulating material.

A gate capping pattern GP may be provided or formed. The gate capping pattern GP may be disposed on the gate electrode GE. The gate capping pattern GP may include an insulating material.

A first insulating layer 130a may be provided or formed. The first insulating layer 130a may be disposed on the source/drain pattern SD and the gate spacer GS. A second insulating layer 140a may be disposed on the first insulating layer 130a. The second insulating layer 140a may be disposed on the gate spacer GS and the gate capping pattern GP. The first and second insulating layers 130a and 140a may include an insulating material. For example, the first and second insulating layers 130a and 140a may include an oxide.

An active contact AC penetrating the first and second insulating layers 130a and 140a may be provided or formed. The active contact AC may be electrically connected to the source/drain pattern SD. The active contact AC may include a conductive material.

Referring to FIG. 12D, a gate contact GC may be provided or formed. At least one of the gate electrodes GE may be electrically connected to the gate contact GC. The gate contact GC may penetrate the second insulating layer 140a and the gate capping pattern GP. The gate contact GC may include a conductive material.

A lower conductive structure 200a may be provided or formed. The lower conductive structure 200a may be in contact with the active contact AC or the gate contact GC. The lower insulating layer 120a may be disposed on the second insulating layer 140a. The lower conductive structure 200a may include a conductive layer COa and a barrier layer BAa.

A liner 300a may be disposed on the lower insulating layer 120a and the lower conductive structure 200a. An interlayer insulating layer 400a may be disposed on the liner 300a. An etch stop layer 500a may be disposed on the interlayer insulating layer 400a. A cover insulating layer 600a may be disposed on the etch stop layer 500a. An upper conductive structure 700a penetrating through the cover insulating layer 600a and the etch stop layer 500a may be provided or formed.

At least one of the plurality of upper conductive structures 700a may be electrically connected to the source/drain pattern SD through the lower conductive structure 200a and the active contact AC. At least one of the plurality of upper conductive structures 700a may be electrically connected to the gate electrode GE through the lower conductive structure 200a and the gate contact GC.

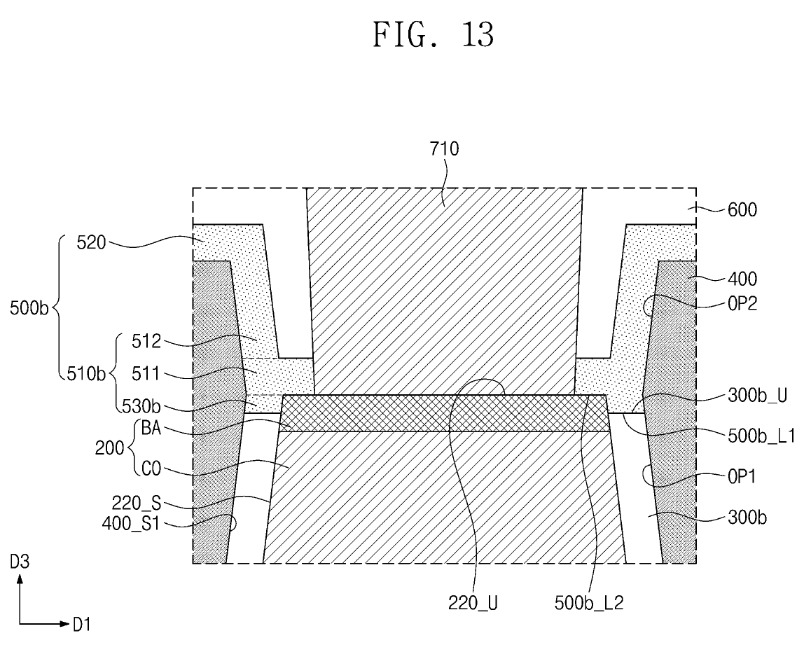

FIG. 13 is an enlarged cross-sectional view of a semiconductor device according to some embodiments. The semiconductor device according to FIG. 13 may be similar to the semiconductor device according to FIGS. 1A to 1E, except as described below.

Referring to FIG. 13, a level of an upper surface 300b_U of a liner 300b may be lower than a level of the upper surface 220_U of the lower conductive structure 200. An etch stop layer 500b may include a first lower surface 500b_L1 in contact with the upper surface 300b_U of the liner 300b and a second lower surface 500b_L2 in contact with the upper surface 220_U of the lower conductive structure 200. A level of the first lower surface 500b_L1 of the etch stop layer 500b may be lower than a level of the second lower surface 500b_L2 of the etch stop layer 500b.

The etch stop layer 500b may include an intervening portion 530b between the first sidewall 400_S1 of the interlayer insulating layer 400 and the sidewall 220_S of the lower conductive structure 200. The intervening portion 530b may be in contact with the first sidewall 400_S1 of the interlayer insulating layer 400 and the sidewall 220_S of the lower conductive structure 200. The first lower surface 500b_L1 of the etch stop layer 500b may be a lower surface of the intervening portion 530b.

The lower portion 510b of the etch stop layer 500b may include the intervening portion 530b. The lower portion 510b of the etch stop layer 500b may be disposed in the first opening OP1 and the second opening OP2. The lower portion 510b of the etch stop layer 500b may include the first portion 511 and the second portion 512 disposed in the second opening OP2, and the intervening portion 530b disposed in the first opening OP1.

A semiconductor device according to embodiments of the disclosure may have improved electrical characteristics of the semiconductor device as a liner includes a low dielectric constant material.

In the semiconductor device according to the embodiments of the disclosure, a occurrence of undercut of an etch stop layer may be prevented, and a formation of voids may be prevented from being formed.

While embodiments are described above, a person skilled in the art may understand that many modifications and variations are made without departing from the spirit and scope of the invention defined in the following claims. Accordingly, the example embodiments of the disclosure should be considered in all respects as illustrative and not restrictive, with the spirit and scope of the invention being indicated by the appended claims.

What is claimed is:

1. A semiconductor device comprising:
a first conductive structure;
a liner in contact with a sidewall of the first conductive structure;
a second conductive structure on the first conductive structure; and
an etch stop layer in contact with a sidewall of the second conductive structure,
wherein a lower surface of the etch stop layer is in contact with an upper surface of the liner.

2. The semiconductor device of claim 1, wherein the upper surface of the liner is coplanar with an upper surface of the first conductive structure.

3. The semiconductor device of claim 1, wherein the upper surface of the liner is in contact with a lower surface of the second conductive structure.

4. The semiconductor device of claim 1, further comprising an interlayer insulating layer on the liner,
wherein the etch stop layer and the second conductive structure are on the interlayer insulating layer,
wherein a first opening and a second opening connected to the first opening are in the interlayer insulating layer,
wherein a width of the first opening decreases as a level of the first opening increases, and
wherein a width of the second opening increases as a level of the second opening increases.

5. The semiconductor device of claim 4, wherein an upper portion of the liner and an upper portion of the first conductive structure are in the first opening, and
wherein a lower portion of the etch stop layer and a lower portion of the second conductive structure are in the second opening.

6. The semiconductor device of claim 1, wherein a level of the upper surface of the liner is lower than a level of an upper surface of the first conductive structure.

7. The semiconductor device of claim 6, wherein the etch stop layer comprises an intervening portion in contact with the sidewall of the first conductive structure, and
wherein the lower surface of the etch stop layer is a lower surface of the intervening portion.

8. A semiconductor device comprising:
a first conductive structure;
a liner on the first conductive structure;
an interlayer insulating layer on the liner;
a second conductive structure on the first conductive structure; and
an etch stop layer on the interlayer insulating layer,
wherein the interlayer insulating layer is between the liner and the etch stop layer,
wherein a first opening and a second opening connected to the first opening are in the interlayer insulating layer,
wherein an upper portion of the first conductive structure is in the first opening,
wherein a lower portion of the second conductive structure is in the second opening, and
wherein a width of the second opening is greater than a width of an upper surface of the first conductive structure.

9. The semiconductor device of claim 8, wherein a width of the first opening decreases as the first opening is closer to the second opening,
wherein a width of the second opening decreases as the second opening is closer to the first opening, and
wherein a width of a lowermost portion of the second opening is greater than a width of the upper surface of the first conductive structure.

10. The semiconductor device of claim 8, wherein an upper portion of the liner is in the first opening, and
wherein a lower portion of the etch stop layer is in the second opening.

11. The semiconductor device of claim 8, wherein the lower portion of the etch stop layer comprises:
a first portion in contact with the second conductive structure; and
a second portion spaced apart from the second conductive structure,
wherein the second portion of the lower portion of the etch stop layer is at a higher level than the first portion of the lower portion of the etch stop layer.

12. The semiconductor device of claim 11, further comprising a cover insulating layer on the etch stop layer,
wherein a portion of the cover insulating layer is between the second conductive structure and the second portion of the lower portion of the etch stop layer.

13. The semiconductor device of claim 8, wherein the second conductive structure extends in a first direction, and
wherein a width of a lower surface of the lower portion of the second conductive structure in the first direction is greater than a width of an upper surface of the upper portion of the first conductive structure in the first direction.

14. The semiconductor device of claim 8, wherein a lower surface of the lower portion of the second conductive structure is in contact with an upper surface of the liner.

15. The semiconductor device of claim 8, wherein an upper portion of the liner is in the first opening, and
wherein a lower portion of the etch stop layer is in the first opening and the second opening.

16. A semiconductor device comprising:
a first conductive structure;
a liner surrounding an upper portion of the first conductive structure;
an interlayer insulating layer surrounding an upper portion of the liner;
a second conductive structure on the first conductive structure;
an etch stop layer on the interlayer insulating layer; and
a cover insulating layer on the etch stop layer,
wherein the interlayer insulating layer is between the liner and the etch stop layer,
wherein a sidewall of the upper portion of the liner is in contact with the interlayer insulating layer, and
wherein an upper surface of the upper portion of the liner is in contact with the etch stop layer.

17. The semiconductor device of claim 16, wherein the second conductive structure extends in a first direction,
wherein a width of a lower surface of the second conductive structure in the first direction is greater than a width of an upper surface of the upper portion of the first conductive structure in the first direction, and
wherein a width of the lower surface of the second conductive structure in a second direction intersecting the first direction is smaller than a width of the upper surface of the upper portion of the first conductive structure in the second direction.

18. The semiconductor device of claim 16, wherein a sidewall of the upper portion of the liner is connected to a sidewall of a lower surface of the etch stop layer.

19. The semiconductor device of claim 16, wherein the upper portion of the first conductive structure comprises a conductive layer and a barrier layer, and
wherein the sidewall of the upper portion of the liner is in contact with a sidewall of the conductive layer and a sidewall of the barrier layer.

20. The semiconductor device of claim 19, wherein the etch stop layer is in contact with an upper surface of the barrier layer.
